(19) United States
(12) Patent Application Publication
(10) Pub. No.: US 2023/0180436 A1
(43) Pub. Date: Jun. 8, 2023

(54) SYSTEM FOR COOLING ELECTRICAL COMPONENTS AND RECYCLING HEAT

(71) Applicant: Treis Blockchain, LLC, Greer, SC (US)

(72) Inventors: Michael Bolick, Greer, SC (US); David Pence, Greer, SC (US); Senter Smith, Greer, SC (US)

(73) Assignee: Treis Blockchain, LLC, Greer, SC (US)

(21) Appl. No.: 18/077,372

(22) Filed: Dec. 8, 2022

Related U.S. Application Data
(63) Continuation of application No. 63/287,499, filed on Dec. 8, 2021.

(51) Int. Cl. H05K 7/20

(52) U.S. Cl. CPC H05K 7/203; H05K 7/20327; H05K 7/20409

(57) ABSTRACT

A system for cooling and recycling heat having a vat to receive an electrical component that generates heat; a pump for flowing a fluid into the vat through a dispensing assembly wherein the dispensing assembly includes an opening for flowing fluid in or around an electrical component whereby the electrical component passes heat to the fluid; a diffuser for directing fluid away from a vertical and linear flow path in the vat and adapted to increase the fluid in and around an electrical component; a weir for receiving heated fluid and directing the heated fluid to an outlet; a heat exchanger for absorbing heat from the heated fluid and using the heated fluid for a subsequent use wherein the fluid is returned at a cooler temperature than when it entered the heat exchanger providing for further use of the fluid for cooling the electrical component in the vat.

### RELATED APPLICATIONS

This application is a non-provisional patent application claiming priority on U.S. provisional patent application 63/287,499 filed Dec. 8, 2021 incorporated by reference.

### BACKGROUND OF THE INVENTION

### 1) Field of the Invention

This system is directed to immersive cooling of computer systems using a first fluid for heat exchange between heat sources such as electrical components, such as motors, batteries, computer, and the like, and a second fluid that exchanges heat with the first fluid wherein the second fluid can provide energy for a subsequent use.

### 2) Description of the Related Art

Electrical components such as motors, batteries, computers, and the like, generate heat. Electrical components generate heat because of the inefficiency of the electricity-conducting elements inside the components. The metals used in electronics have some electrical resistance which results in energy in the component being transferred into heat. Over time, this heat aggregates making the particular electrical component hot. Understanding this heating effect, electrical components, such as a computer processing unit (CPU), are designed to operate at high temperatures which can meet and exceed 200° F. in normal operating environments. As electricity runs through a CPU, or enters a terminal circuit, the electricity is converted into heat. For some high-performance workstations, it is typical for these CPUs to run hot. In some instances, the CPU or other component can operate past recommended limits such as with overclocking a motherboard or running a motor at higher than recommended revolutions per minute. While exceeding recommended operational limits can provide increased performance, it is not without risks. These risks include higher heat, higher voltage generated, reduced equipment lifespan and even risk of fires. Therefore, controlling the heat in these situations is desirable.

There have been several attempts to cool these components using a fan, cooling fluid, heat sinks, cold plates, and others. For example, U.S. Pat. No. 10,136,551 is one attempt to manage the heat from the usual operation of electronic equipment and discloses a method of cooling a computer server in an enclosed room and includes transferring heat generated to a hot plate of a liquid cooling system. Korean Patent 10,196,981 discloses a cooling device that uses a housing to hold a liquid refrigerant, a cooling pipe placed inside the housing, a coolant circulating pump for supplying coolant to the cooling pipe, and a coolant heat exchanger cooling the coolant heated from the coolant pipe. A metal sheet cools the vaporized liquid refrigerant and converts a state of the vaporized liquid refrigerant into a liquid state.

One industry that has seen increased interest in the ability to overclock computers and reduce heat is the cryptocurrency industry. Cryptocurrency mining is the process by which new cryptocurrency denominations (e.g., Bitcoin) are entered into circulation. Mining is also the method where new transactions are verified by the network and used as a critical component of the maintenance and development of a blockchain ledger. Mining is performed using sophisticated hardware that solves an extremely complex computational math problem. The first computer to find the solution to the problem is awarded the next block of bitcoins and the process begins again. Therefore, the more computer power, the higher the chances of profitability. Some miners use overclocking to increase the clock and memory speeds of the computer to higher than recommended speeds in hopes of increasing profits. However, this results in the increased need to manage heat. International Application WO 2021/002823 discloses a coolant for electronic equipment used in cryptocurrency mining. U.S. Pat. No. 9,351,429 discloses an immersion cooling system that enables direct cooling of information handling systems, such as servers, by submerging and operating the physical information handling systems in a volatile (i.e., low boiling point) liquid within the multi-phase heat transfer immersion cooling tank.

In the information technology industry, including cryptocurrency mining, there is an increased use of application-specific integrated circuits (ASICs). ASICs are integrated circuits designed and built to serve a specific purpose or designated application. ASICs are designed to provide fast computational speed as opposed to slower general computer systems, such as personal and business computers having general purpose processors. Typically, an ASIC is designed to perform a specific task, process, or application and balances flexibility against computational speed. Multiple ASICs are placed on a board to form an ASIC hash board. One or more ASIC hash boards can be used for these specific tasks. One such specific task is for cryptocurrency, also known as mining, crypto currency mining or more specifically Bitcoin mining. In mining, ASICs are used for proof-of-work, digital rights management, blockchain and other such systems that have a need for speed and efficiency. One such example of an ASIC assembly is shown in U.S. Pat. No. 10,262,164 and

When mining, factors that affect profitability includes the cost of electricity and hash rate. One method that has been used to improve efficiency in mining is to increase the power delivered to the ASIC which results in a higher hash rate, the ASIC runs at a higher temperature, which increases the heat output and can lead to a shorter lifespan of ASIC processing and even to electrical component, such as an ASIC failure. Even temperatures that exceed 100° C. can lead to damage and failure of an ASIC or other processor.

As well as those discussed above, there have been additional attempts to reduce temperatures of ASICs, processors, and other computer hardware with cooling systems such as the liquid system described in U.S. Pat. No. 7,069,737 and United States Patent Application Publication 2018/0035569. Such systems increase complexity and therefore increase the risk of system failures. Such systems are also more expensive and require more difficult and technical maintenance and repairs.

Other attempts to manage the thermal problems created with overclocking is to use a system that can detect the temperature of a process and can reduce the power delivered to the processer in the event a predetermined temperature is reached. One example is shown in U.S. Pat. No. 8,793,512. However, these systems reduce efficiency as they lower the performance of the calculation rate and hash rate in exchange for keeping the processors under a predetermined temperature.

Another attempt to address the thermal issues with overclocking and processors in general is the use of a heat sink. For example, U.S. Pat. No. 7,382,047 discloses a heat dissipation device that includes a heat sink, fan, and cooling member. The heat sink includes a plurality of fins. The cooling member includes a cold surface attached to one side of the fins and a condensing portion of at least one heat pipe to make the one side of the fins and the condensing portion have a lower temperature. Because the heat sink must be in physical contact with CPU or other processors, there is a practical limit to the size attachment and functionality of heat sinks. Heat sinks must make direct contact with the CPU or processor to function contributing to the limitations of this cooling attempt. An example of a heat sink is shown in U.S. Pat. No. 5,867,365. An additional problem with heat sinks is that they must be securely fastened to the CPU or process. Attention has been given to this problem as shown in U.S. Pat. Nos. 6,600,650; 6,141,220; and 5,638,258. When the heat sink is affixed to the CPU or processor, replacing the CPU or processor requires the replacement of the heat sink, unless the heat sink is removable from the CPU or processor. This problem is magnified when the cooling system is integrated with a power supply or fan, for example, as shown in United States Patent Application Publication 2004/0246677.

Having a more efficient system for significantly cooling an electronic component would be advantageous. Further, the ability to use the heat generated from the electrical component for a subsequent use would also be advantageous. For example, U.S. Pat. No. 10,015,912 discloses a data center includes: a liquid immersion tank that holds an information processing apparatus in a cooling liquid; a cooling apparatus that cools a pipe exposed to outside air and through which the cooling liquid flows from the liquid immersion tank; and a pump apparatus that delivers the cooling liquid from the cooling apparatus to the liquid immersion tank. In this system the heat is simply reduced in pipes that are used to cool electrical components and the heat generated by the electrical components is only discharged into the outside air. It would be advantageous to be able to use the heat generated by the electrical component in a more energy efficient manner.

One method that has growing popularity is immersion cooling, especially in the information technology sector. Immersion cooling operates by directly immersing electronic (including computer) equipment into a bath of cooling fluid. Cooling computer equipment by using fluid immersion has shown to substantially reduce cooling costs and may even be able to reduce the construction costs of data and mining centers. However, providing a system that has sufficient fluid flow over the electrical component in a more even manner is a problem that needs addressing. For example, U.S. Pat. No. 9,086,859 uses individual tanks with cooling fluid wherein each tank has a separate computer component. U.S. Pat. No. 7,724,524 discloses heat generating components and are housed in a liquid sealed enclosure. United States Patent Application Publication discloses a plurality of rack-mountable servers containing heat generating electronic components in a server room including a dielectric liquid cooling apparatus located inside the tank and a secondary cooling apparatus comprising a remote heat exchanger and at least one pump. It would be advantageous to have a cooling system without individually managing container for each electrical component and that could provide for easily removable electrical components with also providing evenly distributed fluid for increasing heat reduction in the electrical components.

An attempt to provide for immersion cooling is showing in U.S. Pat. No. 10,820,446 that discloses a system having a generally rectangular tank adapted to immerse in a dielectric fluid a plurality of appliances in a respective slot. This system circulates the dielectric fluid through the tank and uses a secondary fluid circulation facility to extract heat from the dielectric fluid and dissipate the heat to the environment. A plenum is positioned adjacent to the bottom of the tank and adapted to dispense the dielectric fluid substantially uniformly upwardly through each appliance slot. A weir is integrated horizontally into a long wall of the tank and adapted to facilitate substantially uniform recovery of the dielectric fluid flowing through each appliance slot.

It is an object of the present system to provide an electrical component cooling system which can also capture, and reuse, heat generated by the electrical component.

It is another object of the present system to provide for a cooling system having an open area for receiving multiple electrical components that can be easily inserted and removed from the vat.

It is another object of the present system to provide a more evenly distributed fluid for increasing heat reduction in each electrical component.

### BRIEF SUMMARY OF THE INVENTION

The above objectives are accomplished by providing a system for cooling and recycling heat comprising: a vat configured for receiving an electrical component wherein the electrical component generates heat; a pump for flowing a fluid into the vat through a dispensing assembly wherein the dispensing assembly includes an opening for flowing fluid in or around an electrical component whereby the electrical component passes heat to the fluid; a diffuser included in the dispensing assembly for directing the fluid away from a vertical and linear flow path in the vat and adapted to increase the fluid in and around an electrical component; a weir included in the vat for receiving heated fluid and directing the heated fluid to an outlet; a heat exchange configured for absorbing heat from the heated fluid and using the heated fluid for a subsequent use wherein the fluid is returned to the vat at a cooler temperature than when it entered the heat exchange providing for further use of the fluid for cooling the electrical component in the vat. The fluid can be an oil, natural, synthetic, or other fluid such as a dielectric fluid. The diffuser can be disposed in an interior of a pipe included in the dispensing assembly, exterior to the pipe, a grate wherein the grate can be disposed between the electrical component and the dispensing assembly, slidable attached to the dispensing assembly where the diffuser can include a left position, a right position, and any combination thereof. An opening in dispensing assembly can direct fluid from the dispensing assembly through the diffuser and into the vat. The system can include a second fluid that can absorb heat from the fluid and the second fluid can be used for the subsequent use. A heater can be adapted for increasing a temperature of the second fluid prior to the subsequent use wherein the subsequent use is taken from the group consisting of air heating, generating steam, space heating, conversion into electricity, drying, and any combination thereof. The electrical component is taken from the group consisting of a computer device, computer devices arranged in a rack, motor, generator, miner, and any combination thereof.

The system for immersion cooling electrical components can include a vat configured to receive an electrical component wherein the electrical component generates heat; an inlet defined in the vat; a dispensing assembly disposed in the vat and in fluid communications with the inlet allowing fluid to flow into the vat through an opening defined in the dispensing assembly for injecting fluid into the vat so that heat from the electrical component transfers to the fluid thereby cooling the electrical component; and, a diffuser included in the dispensing assembly and disposed above the opening and adapted for directing a laminar flow path of the fluid to a turbulent flow path of the fluid to increase a circulation of fluid in and around the electrical component.

The system can include a support grate disposed above the dispensing assembly for supporting the electrical component in the vat, a first inlet and the dispensing unit can include a second inlet disposed on an opposite end of the vat wherein the dispensing assembly injects fluid into the vat from opposite ends. The dispensing assembly can include a first section connected to a second section by a restrictor adapted to increase the flow of fluid from the first section to the second section. A weir can be disposed in the vat for receiving heated fluid and directing the heated fluid to an outlet. An outlet can be defined in the vat for transferring heated fluid from the vat to a heat exchanger, wherein the heat exchanger is adapted to receive heated fluid from the vat and to absorb heat from the heated fluid thereby cooling the fluid. The diffuser can include a mesh arrangement disposed in the fluid flow path and the mesh arrangement can be disposed in the fluid flow path. The diffuser can include an angled portion disposed on a pipe included in the dispensing assembly.

The diffuser can be disposed in a housing configured to revive electrical components. The diffuser can include an external projection adapted to direct a laminar flow path of the fluid to a turbulent flow path of the fluid to increase a circulation of fluid in and around the electrical component. A channel can be defined in the diffuser for directing a laminar flow path of the fluid to a turbulent flow path of the fluid to increase a circulation of fluid in and around the electrical component. The electrical component can be taken from the group consisting of central processing unit, application-specific integrated circuit, motor, high performance computer, computing device, field programmable gate array, artificial intelligence machine, and any combination thereof.

The fluid can be a dielectric fluid. The weir can be disposed in the vat and can be against a wall of the vat. The heat exchanger can be adapted to receive heated fluid from the vat and to absorb heat from the heated fluid thereby cooling the fluid wherein the fluid is then transferred back to the dispensing assembly. A grate having openings for supporting the electrical component can be disposed in the vat so that the electrical component is at least partially submerged in the fluid.

### BRIEF DESCRIPTION OF THE SEVERAL VIEWS OF THE DRAWINGS

The construction designed to carry out the invention will hereinafter be described, together with other features thereof. The invention will be more readily understood from a reading of the following specification and by reference to the accompanying drawings forming a part thereof, wherein an example of the invention is shown and wherein:

FIG. 1 is a schematic of aspects of the system.

FIG. 2 is a schematic of aspects of the system.

FIGS. 3A and 3B are perspective views of aspects of the system.

FIG. 4 is a perspective view of aspects of the system.

FIG. 5 is a top-down view of aspects of the system.

FIG. 6 is a side view of aspects of the system.

FIG. 7 is a side view of aspects of the system.

FIG. 8 is a side view of aspects of the system.

FIG. 9 is a side view of aspects of the system.

FIG. 10 is a top-down view of aspects of the system.

FIG. 11 is a perspective view of aspects of the system.

FIGS. 12A and 12B are perspective views of aspects of the invention.

### DETAILED DESCRIPTION OF THE INVENTION

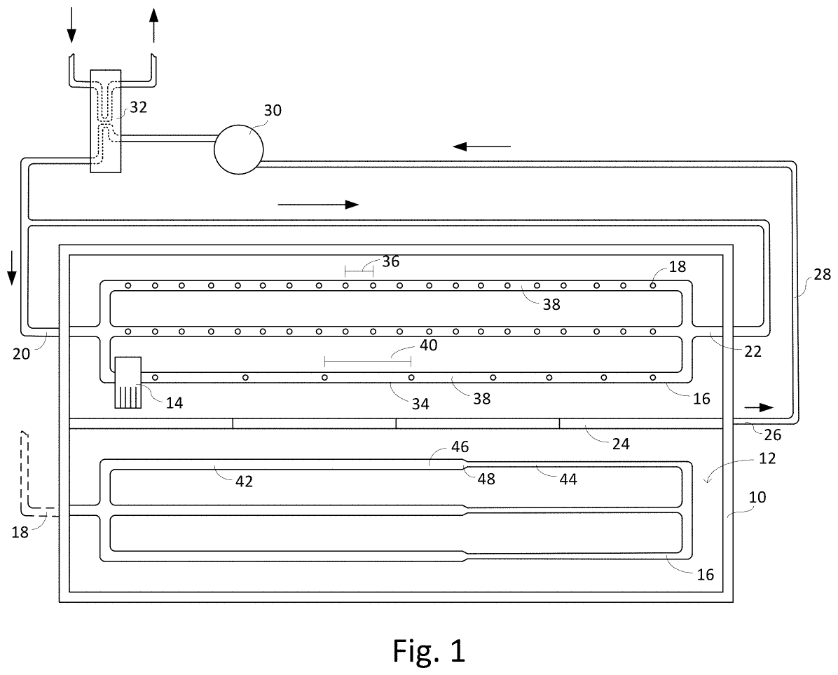

With reference to the drawings, the invention will now be described in more detail. Referring to FIG. 1, a vat 10 has a cavity 12 that can receive various articles including an electrical component 14 and a dispensing assembly 16. The dispensing assembly can be disposed at the lower half of the vat and under the electrical component. The dispensing assembly can include inlets allowing fluid that enters the dispensing assembly to flow into the vat from an opening. The fluid can then be directed under or through the electrical component so that heat from the electrical component is absorbed by the fluid as the fluid flows past or through the electrical component. Fluid can enter the dispending assembly from a single input 18 or through a dual input system having a first input 20 and a second input 22. The fluid can be under pressure as it enters the dispensing assembly so that the fluid flows through the openings and into the vat.

The vat can include a weir 24 that can be adapted as an output for the fluid to exit the vat and a volume control for the fluid level in the vat. The top portion of the weir can be disposed lower than the top edge of the vat so that fluid flowing into the vat will exit the vat through the weir rather than over the side of the vat. The weir can be connected to outlet 26 that can be connected to an outgoing pipe 28 and into a pump. The pump 30 can apply pressure to the fluid so that in one embodiment, the fluid flows into a heat exchanger 32. The heat exchanger can be an open system wherein the fluid is exposed to an environment allowing heat from the fluid to be released into the environment. The heat exchanger can be a closed system wherein the fluid is a first fluid and can be adapted to allow heat radiating from the first fluid to be cooled by the second fluid resulting in the first fluid being cooler and the second fluid being warmer. The heat exchanger can include one or more cold plates, fins, heat sinks, and the like. The second fluid can flow over one or more components of the heat exchanger to cool the components of the heat exchanger. The second fluid can be exposed to the environment for cooling after it is warmed by the first fluid and returned to the heat exchanger for continued cooling operation. The cooled fluid can flow from the heat exchanger to the dispensing assembly for further cooling of the electrical components.

In one embodiment, the fluid is of equal pressure when entering the dispensing assembly so that the pressure at the first input and the pressure at the second input are equal in a range of twenty percent. Therefore, the fluid flows into the vat along a dispensing assembly pipe 34 at generally the same pressure along the openings in the dispensing assembly pipe. In one embodiment, a first dispensing assembly pipe 34 can have openings at a first spacing 36 and a second dispensing pipe 38 can have openings at a second spacing 40. The spacing of the openings can be equal or unequal along the length of a pipe. In one embodiment, the dispensing pipe include a first section 42 and a second section 44. When fluid enters the dispensing assembly at inlet 18 the pressure can drop as the fluid travels along the pipe 46. The fluid can flow through a restriction 48 which can increase the pressure of the fluid at the second section allowing the flow of the fluid to be more evenly distributed along pipe 46.

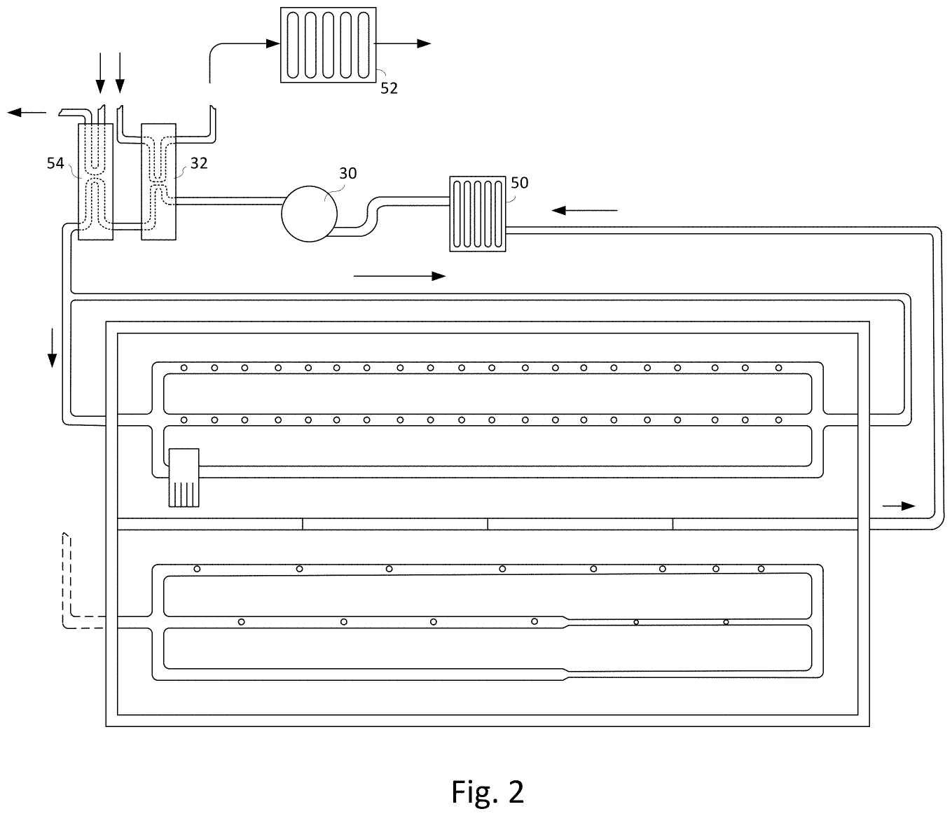

Referring to FIG. 2, the fluid can flow around or into a heater 50 which can increase the temperature of the fluid before the fluid enters the heat exchanger. In some applications, a higher temperature first fluid is desired. For example, the heat exchanger can be adapted to use steam for heating of other application (e.g., rotating a turbine) so that it is desirable for the second fluid (e.g., that which is in contact with the turbine) to be more than 125° C. such as with a steam turbine. The fluid may exit the vat at a temperature less than 60° C. so that the heater can increase the second fluid temperature so that it can be used for the subsequent applications (e.g., steam turbine).

In one embodiment, the heater can be a heat exchanger configured so that the energy from the vat can be used for cooling applications. For example, the heat from the heated fluid exiting the vat can be used to operate an absorption cooling system. In this embodiment, an absorption chiller can be used that uses the heat to create pressure and drive the cycle of the chiller. The absorption chiller can use two coolants, the first of which performs evaporative cooling wherein the heat can be absorbed into the second coolant. Heat is used to reset the two coolants to their initial states that can be used to air-condition buildings using the heat from the vat. Using heat from the vat makes the system more efficient because it cools the electrical components and the heated fluid can be used for air-conditioning (e.g., trigeneration). Some applications include absorption refrigerators such as those used with buildings, recreational vehicles, campers, and caravans.

In one embodiment, the second fluid temperature can be increased with a second heater 52. In this embodiment, it is not necessary to increase the temperature of the first fluid to match the needs of the subsequent use. The subsequent use can be a heat source for heating an area such a room or building, hearing another fluid such as a water boiler or water heater to provide heated water or other subsequent use that typically require a heat source. The fluid can provide a base heat to a second heat source so that the second heat source requires less energy with the fluid heating the second heat source when compared to second heat source being used alone. For example, if a water heater is used for heating water, the heated fluid can leave the vat and can be used by the water heater to increase the water temperature so that the second heater source (e.g., water heater) does not need to raise the temperature of the water from room ambient temperature to the desired temperature. Therefore, the energy needed to heat the water can be reduced as the water heater begins with water at a higher temperature than ambient.

In one embodiment, as second heat exchanger 54 can be used to lower the heat of the first fluid. The second heat exchanger can be connected to a system that can use the head from the first fluid such as heating a living space where the temperatures are not as high as may be needed at the first heat exchanger.

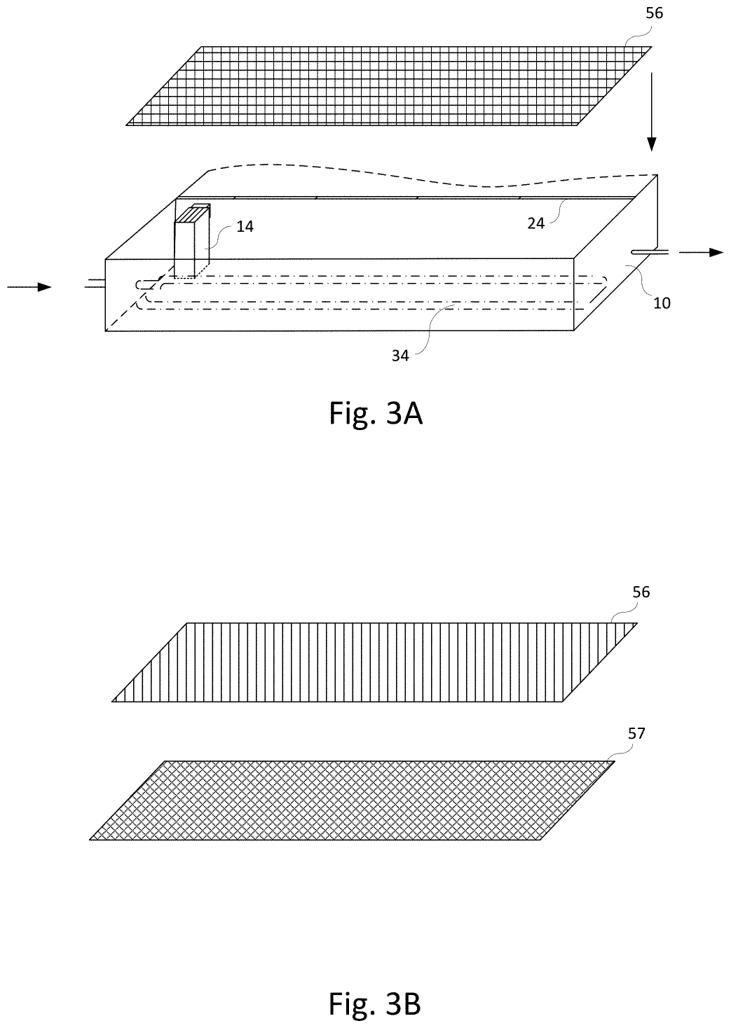

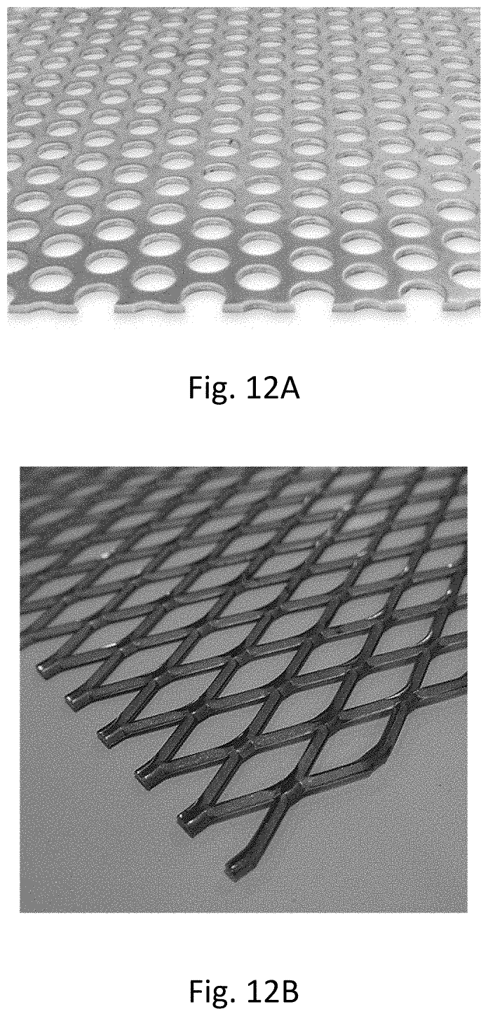

Referring to FIGS. 3A and 3B, the vat 10 can be adapted to receive a grate 56. The grate can include a mesh assembly allowing fluid to pass through the grate. The mesh assembly can include a grate 56 and mesh component 57 as shown in FIG. 3B. The mesh assembly can include one or more sections that can be removable connected as well as can be interlocked. Elements of the grate and the mesh can be parallel, symmetrical, asymmetrical, crossing, and any combination thereof. The grate can be disposed above the dispensing assembly while also supporting the electrical components. Therefore, the precise placement of the electrical components in the vat is not necessary as the grate supporting the electrical component with the electrical component needing to be placed in a rack, slot, or other specifically supporting element. The grate can allow for electrical components to be arranged in the vat in an efficient manner even when each electrical component does not have the same physical dimensions. The grate and mesh, alone or together, can be positioned over the openings in the dispensing assembly and adapted to create turbulence in the fluid as the fluid enters the vat. The grate and mesh can be adapted to provide a more evenly distributed fluid flow, more turbulent fluid flow, provide increased dissipation of the heat in the vat and improve cooling of the electrical components. Some embodiments of the grate and the mesh are shown in FIGS. 12A and 12B.

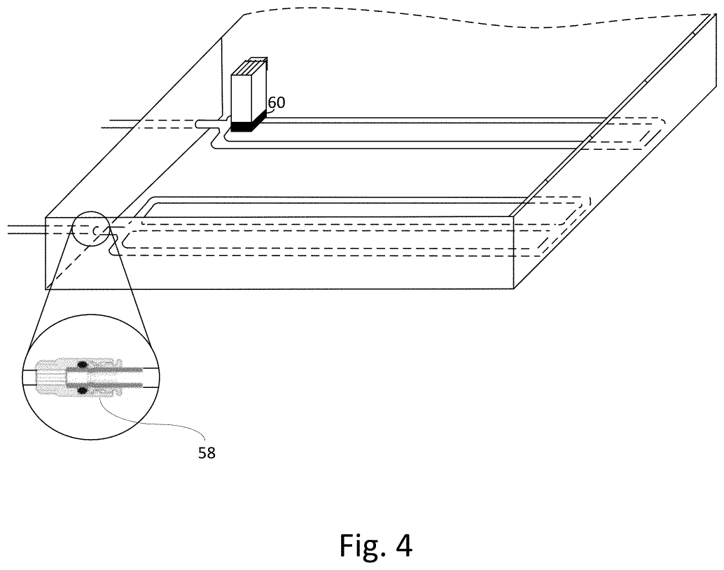

Referring to FIG. 4, the connection of the pipes and dispensing assembly can be a removable connection 58 allowing the dispensing assembly to be easily replaced. The removable connection can be at the vat wall as well as with each pipe or pipe sections in the dispensing assembly. In one embodiment, a boot 60 can be attached to the electrical component or the pipe so that the electrical component can be positioned over an opening in the dispensing assembly to provide for directed fluid around or through the electrical component. The boot can include a diffuser of any type including those discussed herein. The boot can be removable attached to the dispensing assembly and slidable connected along the dispensing assembly. The boot can include opening in the bottom of the boot as well as diffusers to affect the flow of fluid into the electrical component for improved performance.

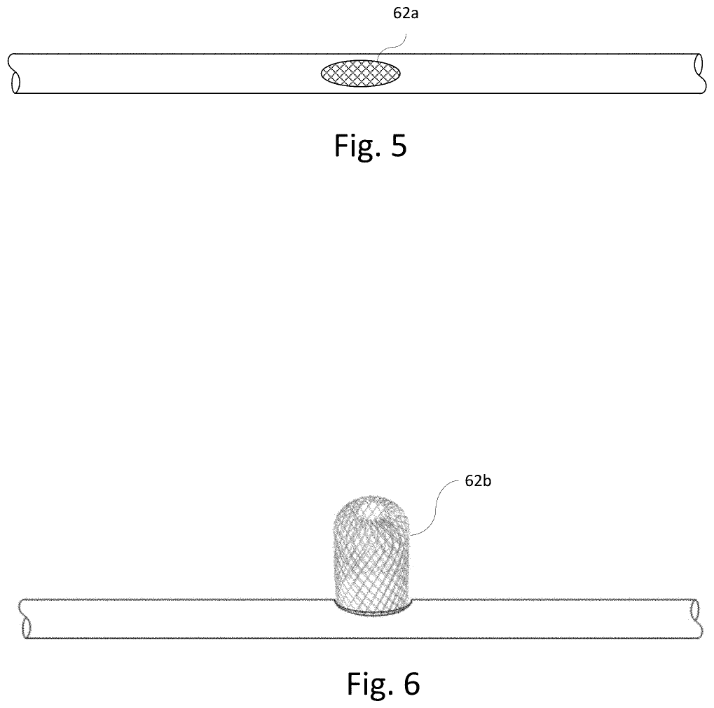

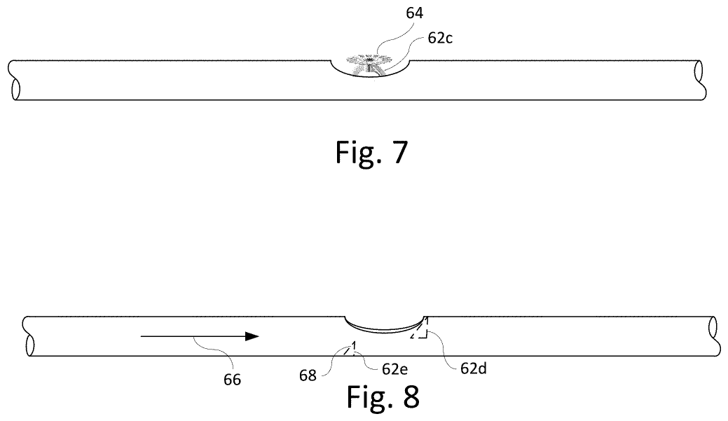

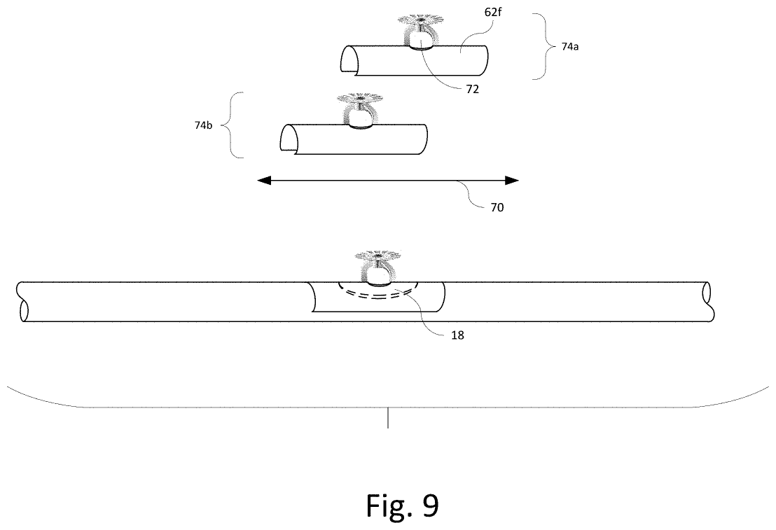

Referring to FIG. 5, the opening in the dispensing assembly can include a diffuser 62a that can create turbulence and otherwise direct the flow of the fluid into the vat in a direction other than a vertical or linear path with turbulent flow rather than laminar flow. The diffuser can provide for a more even flow of fluid around multiple electrical components so that an electrical component does not need to be specifically placed over an opening. Referring to FIG. 6, the diffuser 62b can project away from the pipe and can be configured to support an electrical component in the vat. One or more diffusers can support the electrical component. Referring to FIG. 7, the diffuser 62c can include a fin 64, plate, propeller (stationary or rotating), ramp, shaft, filter, extension, protrusion, concave surface, convex surface, and any combination to create turbulence in the fluid as it exits the pipe to disperse the fluid more evenly in the vat. The diffuser 62c can be flush with a wall of the pipe, recessed or extended away from the pipe. Referring to FIG. 8, the diffuser 62d can be attached to an inner wall of the pipe and adapted to direct fluid through the opening by disrupting linear flow 66 at the fluid travel in the pipe. The diffuser 62e can be disposed on the bottom wall of the pipe and include an angled surface 68. Referring to FIG. 9, the diffuser 62f can be removeable attached to the pipe and travel along a path 70. When attached to the pipe the diffuser can partially cover the opening 18 so that fluid flows through a diffuser opening 72. The diffuser can be placed in the first position 74a shown right and a second position 74b so that the diffuser opening can be moved relative to the pipe. These options allow for flexibility in directing the fluid flow into the vat.

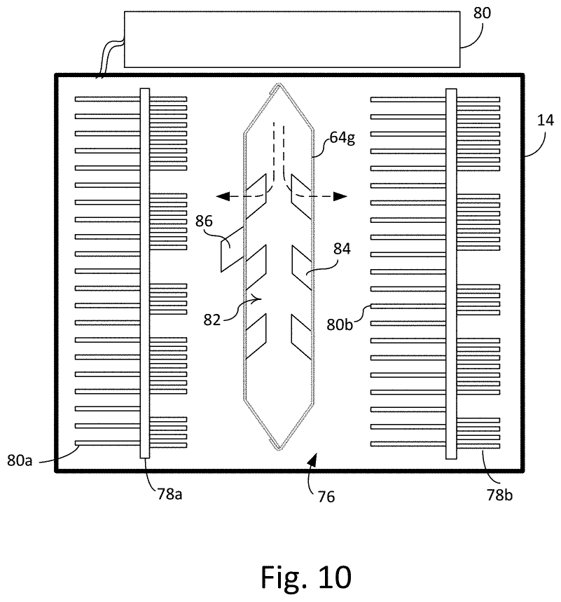

Referring to FIG. 10, an exemplary embodiment of an electrical component is shown from a top-down view. The electrical component 14 can include a housing that has a housing opening 76 extending through the housing that can receive one or more sub-components such as 78a and 78b. The housing can include a connection assembly 80 that provide for electrical connectivity and data connectivity from an electrical and communications bus (not shown) to the housing and electrical components and sub-components. The electrical components can include heat sinks 80a and 80b adapted for increasing the surface area of the electrical component that can contact the fluid. A diffuser 64g can be disposed in the housing and can include a channel 82 that extends through the diffuser for diverting fluid. The diffuser can include internal projections 84 that can direct the flow of the fluid from the pipe opening away from a vertical and linear path to increase the amount of cooled fluid contacting the electrical component. The diffuser can include external projections 86 that can direct the flow of the fluid from the pipe opening away from a vertical and linear path to increase the amount of cooler fluid contacting the electrical component. The diffuser can be disposed at a lower end of the housing generally even with the bottom of the electrical component or even below the electrical component.

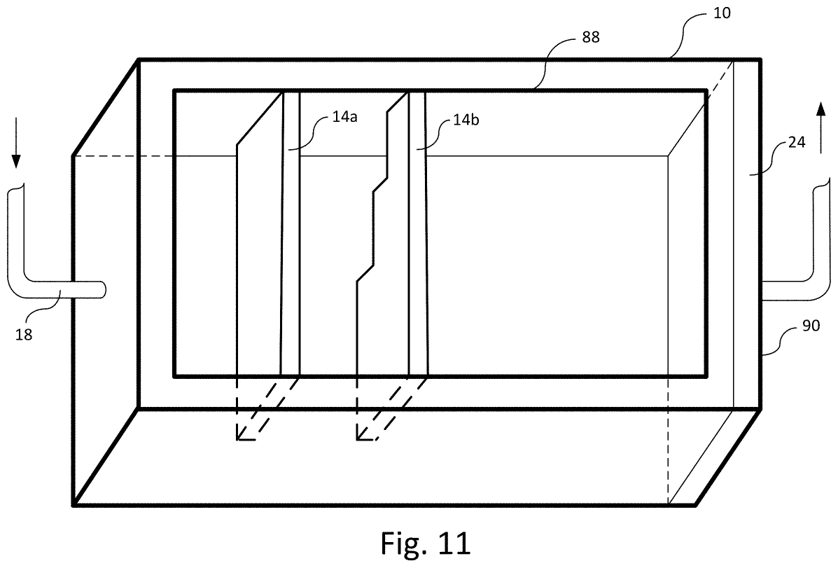

Referring to FIG. 11, the vat can include a rack 88 where electrical components 14a and 14b can be vertically or otherwise placed into or removed from the rack. The electrical components can have varying depths so that the electrical components project into the vat from the rack at varying depths. The weir 24 can be disposed along a shorter side of the vat and along a side wall 90 of the vat. The vat can include one or more racks, one or more electrical components, or any combination thereof. The vat can include components taken from the group consisting of a server, CPU, ASIC, motor, high performance computer, computing device, field programmable gate array, artificial intelligence machine, and any combination thereof.

The subsequent use of the heat from the first fluid includes water and space heating, raising growing and breeding of plants and animals, wood and other material dryings, processing of goods or services such as paints and varnishes, drying of fruits and vegetables, production of rubber, chemical fibers, plastics, alumina, or other materials, and any combination thereof.

It is understood that the above descriptions and illustrations are intended to be illustrative and not restrictive. It is to be understood that changes and variations may be made without departing from the spirit or scope of the following claims. Other embodiments as well as many applications besides the examples provided will be apparent to those of skill in the art upon reading the above description. The scope of the invention should, therefore, be determined not with reference to the above description, but should instead be determined with reference to the appended claims, along with the full scope of equivalents to which such claims are entitled. The disclosures of all articles and references, including patent applications and publications, are incorporated by reference for all purposes. The omission in the following claims of any aspect of subject matter that is disclosed herein is not a disclaimer of such subject matter, nor should it be regarded that the inventor did not consider such subject matter to be part of the disclosed inventive subject matter.

What is claimed is:

1. A system for immersion cooling electrical components comprising:
a vat configured to receive an electrical component wherein the electrical component generates heat;
an inlet defined in the vat;
a dispensing assembly disposed in the vat and in fluid communications with the inlet allowing fluid to flow into the vat
an opening defined in the dispensing assembly for injecting fluid into the vat so that heat from the electrical component transfers to the fluid thereby cooling the electrical component; and,
a diffuser included in the dispensing assembly and disposed above the opening and adapted for directing a laminar flow path of the fluid to a turbulent flow path of the fluid to increase a circulation of fluid in and around the electrical component.

2. The system of claim 1 including a support grate disposed above the dispensing assembly for supporting the electrical component in the vat.

3. The system of claim 1 wherein the inlet is a first inlet and the dispensing unit includes a second inlet disposed on an opposite end of the vat wherein the dispensing assembly injects fluid into the vat from opposite ends.

4. The system of claim 1 wherein the dispensing assembly includes a first section connected to a second section by a restrictor adapted to increase the flow of fluid from the first section to the second section.

5. The system of claim 1 including a weir disposed in the vat for receiving heated fluid and directing the heated fluid to an outlet.

6. The system of claim 1 including an outlet defined in the vat for transferring heated fluid from the vat to a heat exchanger, wherein the heat exchanger is adapted to receive heated fluid from the vat and to absorb heat from the heated fluid thereby cooling the fluid.

7. The system of claim 1 wherein the diffuser includes a mesh arrangement disposed in the fluid flow path.

8. The system of claim 1 wherein the diffuser includes a mesh arrangement disposed in the fluid flow path.

9. The system of claim 1 wherein the diffuser includes an angled portion disposed on a pipe included in the dispensing assembly.

10. A system for immersion cooling electrical components comprising:
a vat configured to receive an electrical component wherein the electrical component generates heat;
a dispensing assembly disposed in the vat adapted to inject fluid into the vat so that heat from the electrical component transfers to the fluid thereby cooling the electrical component; and,
a diffuser included in the vat and adapted for converting a laminar flow path of the fluid to a turbulent flow path of the fluid to increase a circulation of fluid in and around the electrical component.

11. The system of claim 10 wherein the diffuser is disposed in a housing configured to revive electrical components.

12. The system of claim 11 including an external projection adapted to direct a laminar flow path of the fluid to a turbulent flow path of the fluid to increase a circulation of fluid in and around the electrical component.

13. The system of claim 10 including a channel defined in the diffuser for directing a laminar flow path of the fluid to a turbulent flow path of the fluid to increase a circulation of fluid in and around the electrical component.

14. The system of claim 10 wherein the electrical component is taken from the group consisting of central processing unit, application-specific integrated circuit, motor, high performance computer, computing device, field programmable gate array, artificial intelligence machine, and any combination thereof.

15. The system of claim 10 wherein the fluid is a dielectric fluid.

16. The system of claim 10 including a weir disposed in the vat for receiving heated fluid and directing the heated fluid to an outlet.

17. The system of claim 16 wherein the weir is disposed against a wall of the vat.

18. A system for immersion cooling electrical components comprising:
a vat configured to receive an electrical component wherein the electrical component generates heat;
a dispensing assembly disposed in the vat adapted to inject fluid into the vat through an inlet defined in the vat so that heat from the electrical component transfers to the fluid thereby cooling the electrical component;
a weir disposed in the vat for receiving heated fluid and transferring the heated fluid to a heat exchanged in fluid communications with the weir;
a diffuser included in the dispensing assembly and adapted for converting a laminar flow path of the fluid to a turbulent flow path of the fluid to increase a circulation of fluid in and around the electrical component.

19. The system of claim 18 including a heat exchanger wherein the heat exchanger is adapted to receive heated fluid from the vat and to absorb heat from the heated fluid thereby cooling the fluid wherein the fluid is then transferred back to the dispensing assembly.

20. The system of claim 18 including a grate having openings for supporting the electrical component within the vat so that the electrical component is at least partially submerged in the fluid.
